(19) United States
(12) Patent Application Publication
(10) Pub. No.: US 2025/0120087 A1
(43) Pub. Date: Apr. 10, 2025

(54) MEMORY STRUCTURE AND MANUFACTURING METHOD THEREOF

(71) Applicant: United Microelectronics Corp., Hsinchu (TW)

(72) Inventors: Jen Yang Hsueh, Tainan City (TW); Chien-Hung Chen, Hsinchu City (TW); Tzu-Ping Chen, Hsinchu County (TW); Chia-Hui Huang, Tainan City (TW); Chia-Wen Wang, Tainan City (TW); Chih-Yang Hsu, Tainan City (TW); Ling Hsiu Chou, Tainan City (TW)

(73) Assignee: United Microelectronics Corp., Hsinchu (TW)

(21) Appl. No.: 18/502,091

(22) Filed: Nov. 6, 2023

(30) Foreign Application Priority Data
Oct. 7, 2023 (CN) 202311286186.7

(51) Int. Cl. H10B 43/30; H10B 41/30

(52) U.S. Cl. CPC H10B 43/30; H10B 41/30

(57) ABSTRACT

Provided are a memory structure and a manufacturing method thereof. The memory structure includes first and second gates, a dielectric hump, a first spacer, a charge storage layer, a gate dielectric layer, a high-k layer and doped regions. The first and the second gates are disposed on a substrate. The dielectric hump is disposed on the substrate between the first gate and the second gate. The first spacer is disposed on a sidewall of the dielectric hump. The charge storage layer is disposed between the first gate and the substrate. The gate dielectric layer is disposed between the second gate and the substrate. The high-k layer is disposed between the first gate and the charge storage layer and between the second gate and the gate dielectric layer. The doped regions are disposed in the substrate at two sides of the first gate and at two sides of the second gate.

### CROSS-REFERENCE TO RELATED APPLICATION

This application claims the priority benefit of China application serial no. 202311286186.7, filed on Oct. 7, 2023. The entirety of the above-mentioned patent application is hereby incorporated by reference herein and made a part of this specification.

### BACKGROUND

### Technical Field

The present invention relates to a memory structure, and in particular to a memory structure including a memory cell including a high dielectric constant (high-k) layer and a silicon-oxide-nitride-oxide-silicon (SONOS) stacked configuration.

### Description of Related Art

In existing memories, a memory cell including a high-k layer and a SONOS stacked configuration may be called a HKSONOS memory cell. In a process of the memory including the HKSONOS memory cell, after forming the gate of the HKSONOS memory cell and the gate of the select transistor or other transistors, a part of the high-k layer formed on the substrate may be removed, and only the high-k layer under the gates is remained.

However, in the above process, the high-k material is often remained on the substrate between the HKSONOS memory cell and the transistor. As a result, in the subsequent process, the residual high-k material may cause pollution and affect the yield of the final product, and even cause pollution problems to the process equipment.

### SUMMARY

The present invention provides a memory structure and a manufacturing method thereof, which may avoid the high-k material remaining on the substrate.

The memory structure of the present invention includes a first gate, a second gate, a dielectric hump, a first spacer, a charge storage layer, a gate dielectric layer, a high-k layer and doped regions. The first gate and the second gate are disposed on a substrate. The dielectric hump is disposed on the substrate between the first gate and the second gate. The first spacer is disposed on a sidewall of the dielectric hump. The charge storage layer is disposed between the first gate and the substrate. The gate dielectric layer is disposed between the second gate and the substrate. The high-k layer is disposed between the first gate and the charge storage layer and between the second gate and the gate dielectric layer. The doped regions are disposed in the substrate at two sides of the first gate and at two sides of the second gate.

In an embodiment of the memory structure of the present invention, a material of the first spacer includes silicon nitride.

In an embodiment of the memory structure of the present invention, the gate dielectric layer is extended to be connected to the dielectric hump.

In an embodiment of the memory structure of the present invention, the first spacer is located on the gate dielectric layer.

In an embodiment of the memory structure of the present invention, the memory structure further includes a second spacer and a third spacer, wherein the second spacer is disposed on the sidewalls of the first gate, and the third spacer is disposed on the sidewalls of the second gate.

In an embodiment of the memory structure of the present invention, the charge storage layer is further located between the second spacer and the substrate, and the gate dielectric layer is further located between the third spacer and the substrate.

In an embodiment of the memory structure of the present invention, a material of the first gate and the second gate includes polysilicon.

In an embodiment of the memory structure of the present invention, a material of the first gate and the second gate includes metal.

In an embodiment of the memory structure of the present invention, the memory structure further includes a first metal silicide layer and a second metal silicide layer, wherein the first metal silicide layer is disposed on the doped region located at one side of the first gate away from the second gate, and the second metal silicide layer is disposed at one side of the second gate away from the first gate.

In an embodiment of the memory structure of the present invention, the memory structure further includes a first contact and a second contact, wherein the first contact is electrically connected to the doped region located at one side of the first gate away from the second gate, and the second contact is electrically connected to the doped region located at one side of the second gate away from the first gate.

The manufacturing method of the memory structure of the present invention includes the following steps. A pad layer is formed on a substrate. A charge storage layer is formed on the substrate and the pad layer. A part of the pad layer and the charge storage layer thereon are removed, so that a remained portion of the pad layer forms a dielectric hump. A dielectric layer is formed on the substrate exposed by the charge storage layer and the dielectric hump. A first spacer is formed on a sidewall of the dielectric hump. A high-k layer is formed on the substrate, wherein the high-k layer covers the charge storage layer, the dielectric hump, the first spacer and the dielectric layer. A first gate is formed on the high-k layer on the charge storage layer. A second gate is formed on the high-k layer on the dielectric layer. A part of the high-k layer is removed to remain the high-k layer under the first gate and under the second gate. Doped regions are formed in the substrate at two sides of the first gate and at two sides of the second gate.

In an embodiment of the manufacturing method of the memory structure of the present invention, a material of the first spacer includes silicon nitride.

In an embodiment of the manufacturing method of the memory structure of the present invention, a forming method of the first spacer includes the following steps. A spacer material layer is formed on the charge storage layer, the dielectric hump and the dielectric layer. An anisotropic etching process is performed to remove the spacer material layer on a top surface of the charge storage layer and a top surface of the dielectric layer.

In an embodiment of the manufacturing method of the memory structure of the present invention, the manufacturing method further includes forming a second spacer on the sidewalls of the first gate and a third spacer on the sidewalls of the second gate after removing the part of the high-k layer and before forming the doped regions.

In an embodiment of the manufacturing method of the memory structure of the present invention, a method of forming the second spacer and the third spacer includes the following steps. A spacer material layer is formed on the substrate, wherein the spacer material layer covers a top surface of the first gate and a top surface of the second gate. A part of the spacer material layer is removed to form the second spacer and the third spacer.

In an embodiment of the manufacturing method of the memory structure of the present invention, a method for removing the part of the spacer material layer includes the following steps. A chemical mechanical polishing (CMP) process is performed on the spacer material layer to remove a part of the spacer material layer. An anisotropic etching process is performed on a remained portion of the spacer material layer until the top surface of the first gate and the top surface of the second gate are exposed.

In an embodiment of the manufacturing method of the memory structure of the present invention, a material of the first gate and the second gate includes polysilicon.

In an embodiment of the manufacturing method of the memory structure of the present invention, the manufacturing method further includes the following steps. The polysilicon is removed. A metal material is formed on the high-k layer.

In an embodiment of the manufacturing method of the memory structure of the present invention, the manufacturing method further includes forming a first metal silicide layer on the doped region at one side of the first gate away from the second gate and a second metal silicide layer on the doped region at one side of the second gate away from the first gate after forming the doped regions.

In an embodiment of the manufacturing method of the memory structure of the present invention, the manufacturing method further includes forming a first contact electrically connected to the doped region located at one side of the first gate away from the second gate and a second contact electrically connected to the doped region located at one side of the second gate away from the first gate after forming the doped regions.

Based on the above, during the manufacturing process of the memory structure of the present invention, the first spacer is formed on the sidewall of the dielectric hump between the first gate and the second gate, so that the subsequently formed high-k layer may be smoothly formed on the sidewall of the dielectric hump. Therefore, when using the first gate and the second gate as the etching mask to remove the high-k layer, it may effectively prevent the high-k material from remaining around the dielectric hump, thereby preventing the residual high-k material contaminating subsequent processes and the final product.

### BRIEF DESCRIPTION OF THE DRAWINGS

FIGS. 1A to 1H are schematic cross-sectional views of the manufacturing process of the memory structure of the present invention embodiment.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

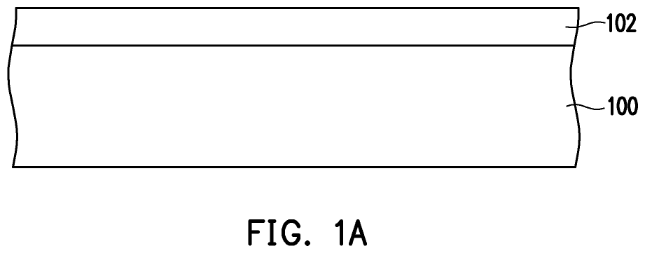

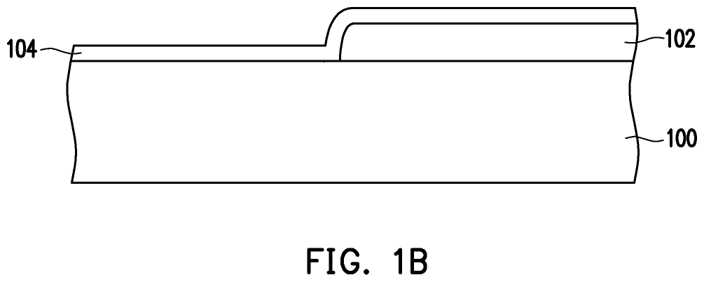

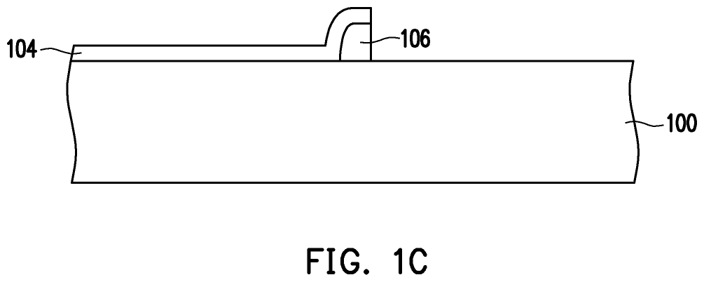

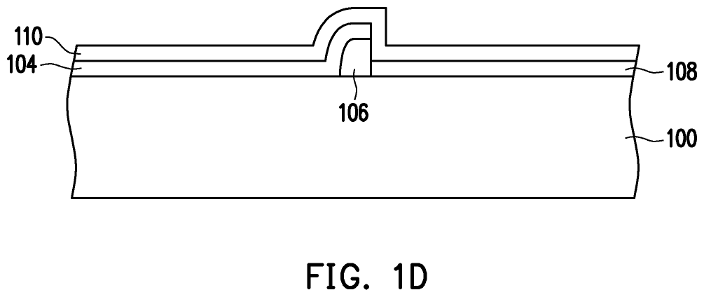

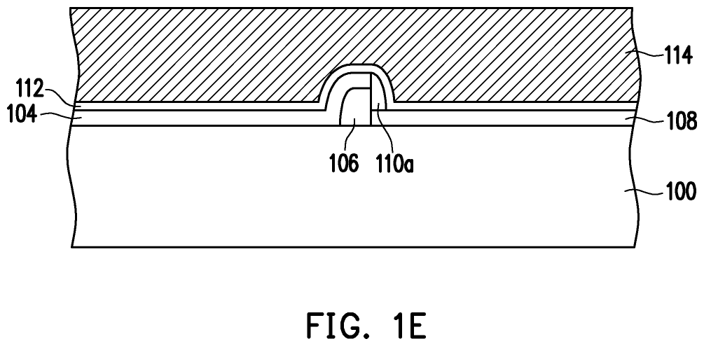

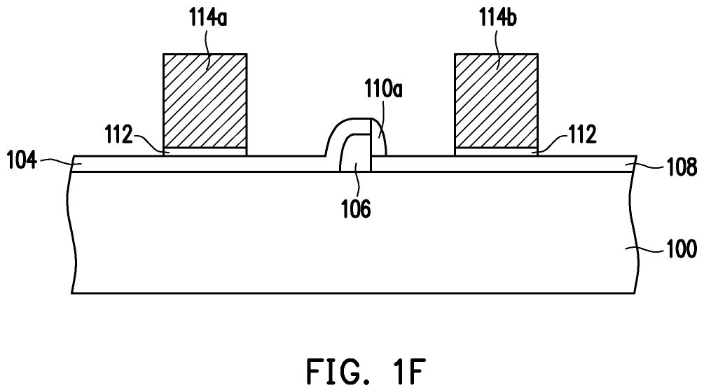

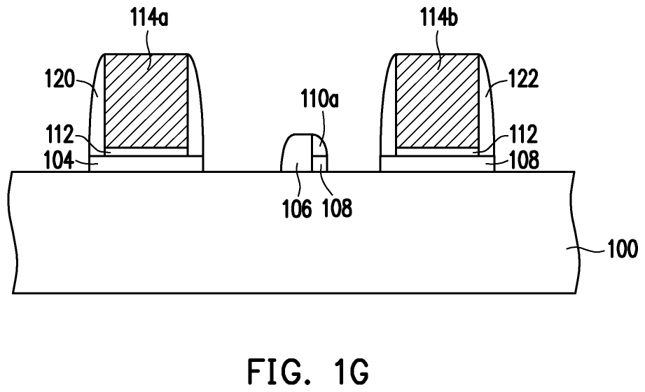

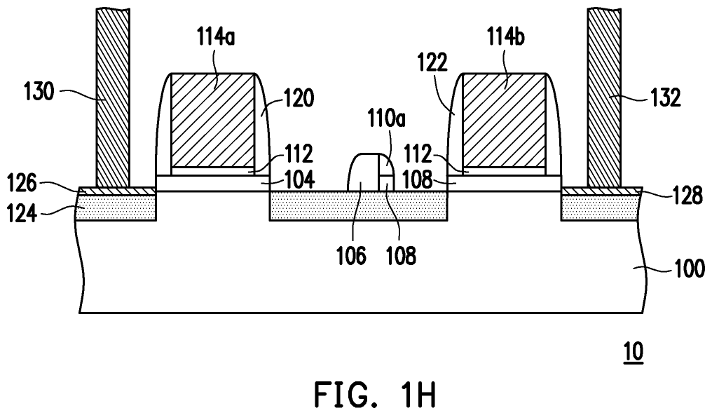

FIGS. 1A to 1H are schematic cross-sectional views of the manufacturing process of the memory structure of the present invention embodiment.

Referring to FIG. 1A, a substrate 100 is provided. In the present embodiment, the substrate 100 is, for example, a silicon substrate. Then, a pad layer 102 is formed on the substrate 100. In the present embodiment, the material of the pad layer 102 is, for example, silicon oxide, and the forming method thereof is, for example, a thermal oxidation process, but the present invention is not limited thereto.

Referring to FIG. 1B, the pad layer 102 in the region where a memory cell is to be formed is removed. The method for removing the pad layer 102 in the region where the memory cell is to be formed may include the following steps, but the present invention is not limited thereto. First, a patterned mask layer (not shown) may be formed on the substrate 100. The patterned mask layer exposes the region where the memory cell is to be formed. Next, an anisotropic etching process may be performed to remove the exposed pad layer 102. Afterwards, the patterned mask layer is removed. After removing the patterned mask layer, a cleaning process may be performed to remove etching by-products and impurities on the substrate 100. At this time, the corners at the ends of the pad layer 102 may be slightly removed to form rounded corners.

After removing the pad layer 102 in the region where the memory cell is to be formed, a charge storage layer 104 is formed on the substrate 100. The charge storage layer 104 covers the substrate 100 and the remained pad layer 102. In the present embodiment, the charge storage layer 104 is, for example, composed of a silicon oxide layer, a silicon nitride layer and another silicon oxide layer stacked in sequence, which is a so-called ONO stacked layer, but the present invention is not limited thereto. In addition, the forming method of the charge storage layer 104 is well known to those skilled in the art and will not be described further here.

Referring to FIG. 1C, a part of the charge storage layer 104 is removed to remain the charge storage layer 104 in the region where the memory cell is to be formed. The method for removing the part of the charge storage layer 104 may include the following steps, but the present invention is not limited thereto. First, a patterned mask layer (not shown) is formed on the substrate 100. The patterned mask layer covers the region where the memory cell is to be formed. Next, an anisotropic etching process is performed to remove the exposed charge storage layer 104. Afterwards, the patterned mask layer is removed. During the anisotropic etching process, in addition to removing the exposed charge storage layer 104, the underlying pad layer 102 may also be removed at the same time to expose the substrate 100.

In the present embodiment, in order to avoid the positional shift of the patterned mask layer causing the charge storage layer 104 in the region where the memory cell is to be formed to be removed, the patterned mask layer usually additionally covers the charge storage layer 104 around the region where the memory cell is to be formed. In this way, after the anisotropic etching process, a part of the charge storage layer 104 and a part of the pad layer 102 located thereunder may be remained around the region where the memory cell is to be formed. In the present embodiment, the pad layer 102 remained around the region where the memory cell is to be formed forms a dielectric hump 106, and the charge storage layer 104 covers the top surface and a part of the sidewalls of the dielectric hump 106. In addition, the top corner of the dielectric hump 106 adjacent the region where the memory cell is to be formed are rounded.

Referring to FIG. 1D, a dielectric layer 108 may be formed on the substrate 100 exposed by the charge storage layer 104 and the dielectric hump 106, so that the dielectric hump 106 and the dielectric layer 108 are connected with each other. In the present embodiment, the material of the dielectric layer 108 is, for example, silicon oxide, and the forming method thereof is, for example, a thermal oxidation process or a chemical vapor deposition (CVD) process, but the present invention is not limited thereto. The dielectric layer 108 may be used to form a gate dielectric layer of a transistor in a memory structure of the present embodiment. Afterwards, a spacer material layer 110 may be conformally formed on the substrate 100. In the present embodiment, the material of the spacer material layer 110 is, for example, silicon nitride, and the forming method thereof is, for example, a CVD process, but the present invention is not limited thereto.

Referring to FIG. 1E, an anisotropic etching process is performed on the spacer material layer 110 to remove the spacer material layer 110 on the top surface of the charge storage layer 104 and the top surface of the dielectric layer 108, while remaining the spacer material layer 110 on the sidewall of the dielectric hump 106. That is, in the present embodiment, a first spacer 110a may be formed on the sidewall of the dielectric hump 106, and the first spacer 110a may be located on the dielectric layer 108. Since the top corner of the dielectric hump 106 adjacent to the region where the memory cell is to be formed is rounded, no spacer may be formed on the sidewall of the dielectric hump 106 adjacent to the region where the memory cell is to be formed after the above anisotropic etching process.

After forming the first spacer 110a, a high-k layer 112 may be conformally formed on the substrate 100. The high-k layer 112 covers the charge storage layer 104, the dielectric hump 106, the first spacer 110a and the dielectric layer 108. In the present embodiment, the high-k layer 112 refers to a dielectric layer with a dielectric constant greater than 4 in the present technical field. The material of the high-k layer 112 may be aluminum oxide (Al₂O₃), tantalum oxide (Ta₂O₃), titanium oxide (TiO₂), yttrium oxide (Y₂O₃), zirconium oxide (ZrO₂), hafnium oxide (HfO₂), lanthanum oxide (La₂O₃) etc., and the present invention does not limit this.

After that, a gate material layer 114 may be formed on the high-k layer 112. In the present embodiment, the material of the gate material layer 114 may be polysilicon. The thickness of the gate material layer 114 is, for example, between 800 Å and 1200 Å. After the gate material layer 114 is formed, a planarization process may be optionally formed on the gate material layer 114 so that the gate material layer 114 may have a flat surface and a desired thickness. In the present embodiment, the planarization process is, for example, a CMP process. In addition, after the planarization process, depending on actual needs, an etching-back process may be performed on the gate material layer 114 to more accurately control the thickness of the remained gate material layer 114.

Referring to FIG. 1F, a patterning process may be performed on the gate material layer 114 to form a first gate 114a on the high-k layer 112 on the charge storage layer 104 and a second gate 114b on the high-k layer 112 on the dielectric layer 108. The first gate 114a may be used as a control gate of the memory cell in the memory structure of the present embodiment, and the second gate 114b may be used as a gate of a selection transistor, a selection gate, in the memory structure of the present embodiment. Afterwards, an anisotropic etching process may be performed by using the first gate 114a and the second gate 114b as the etching mask to remove a part of the high-k layer 112 and remain the high-k layer 112 under the first gate 114a and the second gate 114b.

In the present embodiment, since the dielectric hump 106 is formed through an anisotropic etching process, the dielectric hump 106 may have a substantially vertical sidewall. After the first spacer 110a is formed on the sidewall of the dielectric hump 106, since the sidewall of the first spacer 110a is a non-substantially vertical sidewall, usually with a curved surface, the high-k layer 112 may be formed smoothly on the sidewalls of the dielectric hump 106 in the step described in FIG. 1E. In this way, in the step described in FIG. 1F, when the high-k layer 112 is removed by using the first gate 114a and the second gate 114b as the etching mask, the high-k layer 112 may be effectively prevented from remaining around the dielectric hump 106. That is, there is no high-k material remained between the first gate electrode 114a and the second gate electrode 114b, thereby avoiding the problem of residual high-k material contaminating subsequent processes and the final product.

Referring to FIG. 1G, a second spacer 120 may be formed on the sidewalls of the first gate 114a and a third spacer 122 may be formed on the sidewalls of the second gate 114b. In the present embodiment, the top surface of the second spacer 120 may be coplanar with the top surface of the first gate 114a, and the top surface of the third spacer 122 may be coplanar with the top surface of the second gate 114b.

The forming method of the second spacer 120 and the third spacer 122 may include the following steps. First, a spacer material layer (not shown) may be formed on the substrate 100. The spacer material layer covers the top surface of the first gate 114a and the top surface of the second gate 114b. The material of the spacer material layer is, for example, silicon nitride, and the forming method thereof is, for example, a CVD process. Then, a CMP process may be performed on the spacer material layer to remove a part of the spacer material layer to reduce the thickness of the spacer material layer. After that, an anisotropic etching process is performed on the remained spacer material layer until the top surface of the first gate 114a and the top surface of the second gate 114b are exposed.

Next, an etching process is performed to remove the charge storage layer 104 located at two sides of the first gate 114a and the dielectric layer 108 located at two sides of the second gate 114b. In the present embodiment, the charge storage layer 104 and the dielectric layer 108 are removed by using the first gate 114a, the second spacer 120, the second gate 114b, the third spacer 122 and the first spacer 110a as the mask. Therefore, the remained charge storage layer 104 is located between the second spacer 120 and the substrate 100 in addition to being located between the high-k layer 112 and the substrate 100, and the retained dielectric layer 108 is located between the third spacer 122 and the substrate 100 in addition to being located between the high-k layer 112 and the substrate 100. The dielectric layer 108 under the second gate 114b may be used as a gate dielectric layer of a transistor. In addition, during the above etching process, the dielectric hump 106 may also be partially removed depending on the etching time.

Referring to FIG. 1H, using the first gate 114a, the second spacer 120, the second gate 114b and the third spacer 122 as the mask, an ion implantation process is performed to form doped regions 124 in the substrates at two sides of the first gate 114a and at two sides of the second gate 114b.

Next, a first metal silicide layer 126 may be formed on the doped region 124 at one side of the first gate 114a away from the second gate 114b, and a second metal silicide layer 128 may be formed on the doped region 124 at one side of the second gate 114b away from the first gate 114a. In the memory structure of the present embodiment, since the doped region 124 between the first gate 114a and the second gate 114b is floating, there is no need to form a metal silicide layer on the doped region 124 between the first gate 114a and the second gate 114b. Thereafter, a first contact 130 connected to the first metal silicide layer 126 and a second contact 132 connected to the second metal silicide layer 128 may be formed. In this way, a memory structure 10 of the present embodiment is formed.

During the manufacturing process of the memory structure 10 of the present embodiment, the first spacer 110a is formed on the sidewall of the dielectric hump 106 between the first gate 114a and the second gate 114b, so that the subsequently formed high-k layer 112 may be smoothly formed on the sidewall of the dielectric hump 106. In this way, when the high-k layer 112 is removed by using the first gate 114a and the second gate 114b as the etching mask, the high-k layer 112 may be effectively prevented from remaining around the dielectric hump 106, thereby avoiding the residual high-k material contaminating subsequent processes and final products.

In addition, in the steps in FIG. 1G, after the second spacer 120 and the third spacer 122 are formed, a replacement metal gate (RMG) process (or a gate-last process) may be further performed.

For example, in the above embodiment, the material of the first gate 114a and the second gate 114b is polysilicon. Therefore, after forming the second spacer 120 and the third spacer 122, the polysilicon material forming the first gate 114a and the second gate 114b may be removed, and then a metal material may be filled in the region wherein the polysilicon material is removed to form a metal layer as the first gate 114a and the second gate 114b on the high-k layer 112.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory structure, comprising:
a first gate and a second gate, disposed on a substrate;
a dielectric hump, disposed on the substrate between the first gate and the second gate;
a first spacer, disposed on a sidewall of the dielectric hump;
a charge storage layer, disposed between the first gate and the substrate;
a gate dielectric layer, disposed between the second gate and the substrate;
a high dielectric constant (high-k) layer, disposed between the first gate and the charge storage layer and between the second gate and the gate dielectric layer; and
doped regions, disposed in the substrate at two sides of the first gate and at two sides of the second gate.

2. The memory structure of claim 1, wherein a material of the first spacer comprises silicon nitride.

3. The memory structure of claim 1, wherein the gate dielectric layer is extended to be connected to the dielectric hump.

4. The memory structure of claim 3, wherein the first spacer is located on the gate dielectric layer.

5. The memory structure of claim 1, further comprising a second spacer and a third spacer, wherein the second spacer is disposed on the sidewalls of the first gate, and the third spacer is disposed on the sidewalls of the second gate.

6. The memory structure of claim 5, wherein the charge storage layer is further located between the second spacer and the substrate, and the gate dielectric layer is further located between the third spacer and the substrate.

7. The memory structure of claim 1, wherein a material of the first gate and the second gate comprises polysilicon.

8. The memory structure of claim 1, wherein a material of the first gate and the second gate comprises metal.

9. The memory structure of claim 1, further comprising a first metal silicide layer and a second metal silicide layer, wherein the first metal silicide layer is disposed on the doped region located at one side of the first gate away from the second gate, and the second metal silicide layer is disposed at one side of the second gate away from the first gate.

10. The memory structure of claim 1, further comprising a first contact and a second contact, wherein the first contact is electrically connected to the doped region located at one side of the first gate away from the second gate, and the second contact is electrically connected to the doped region located at one side of the second gate away from the first gate.

11. A manufacturing method of a memory structure, comprising:
forming a pad layer on a substrate;
forming a charge storage layer on the substrate and the pad layer;
removing a part of the pad layer and the charge storage layer thereon, so that a remained portion of the pad layer forms a dielectric hump;
forming a dielectric layer on the substrate exposed by the charge storage layer and the dielectric hump;
forming a first spacer on a sidewall of the dielectric hump;
forming a high-k layer on the substrate, wherein the high-k layer covers the charge storage layer, the dielectric hump, the first spacer and the dielectric layer;
forming a first gate on the high-k layer on the charge storage layer;
form a second gate on the high-k layer on the dielectric layer;
removing a part of the high-k layer to remain the high-k layer under the first gate and under the second gate; and
forming doped regions in the substrate at two sides of the first gate and at two sides of the second gate.

12. The manufacturing method of claim 11, wherein a material of the first spacer comprises silicon nitride.

13. The manufacturing method of claim 11, wherein a forming method of the first spacer comprises:
forming a spacer material layer on the charge storage layer, the dielectric hump and the dielectric layer; and
performing an anisotropic etching process to remove the spacer material layer on a top surface of the charge storage layer and a top surface of the dielectric layer.

14. The manufacturing method of claim 11, further comprising forming a second spacer on the sidewalls of the first gate and a third spacer on the sidewalls of the second gate after removing the part of the high-k layer and before forming the doped regions.

15. The manufacturing method of claim 14, wherein a method of forming the second spacer and the third spacer comprises:
forming a spacer material layer on the substrate, wherein the spacer material layer covers a top surface of the first gate and a top surface of the second gate; and
removing a part of the spacer material layer to form the second spacer and the third spacer.

16. The manufacturing method of claim 15, wherein a method for removing the part of the spacer material layer comprising:
performing a chemical mechanical polishing process on the spacer material layer to remove a part of the spacer material layer; and
performing an anisotropic etching process on a remained portion of the spacer material layer until the top surface of the first gate and the top surface of the second gate are exposed.

17. The manufacturing method of claim 11, wherein a material of the first gate and the second gate comprises polysilicon.

18. The manufacturing method of claim 17, further comprising:
removing the polysilicon; and
forming a metal material on the high-k layer.

19. The manufacturing method of claim 11, further comprising forming a first metal silicide layer on the doped region at one side of the first gate away from the second gate and a second metal silicide layer on the doped region at one side of the second gate away from the first gate after forming the doped regions.

20. The manufacturing method of claim 11, further comprising forming a first contact electrically connected to the doped region located at one side of the first gate away from the second gate and a second contact electrically connected to the doped region located at one side of the second gate away from the first gate after forming the doped regions.
